(19) United States
(12) Patent Application Publication
(10) Pub. No.: US 2023/0253390 A1
(43) Pub. Date: Aug. 10, 2023

(54) SEMICONDUCTOR PACKAGE ASSEMBLY

(71) Applicant: MEDIATEK INC., Hsinchu City (TW)

(72) Inventors: Ruey-Bo SUN, Hsinchu City (TW); Chih-Chun HSU, Hsinchu City (TW); Sheng-Mou LIN, Hsinchu City (TW)

(21) Appl. No.: 18/154,413

(22) Filed: Jan. 13, 2023

Related U.S. Application Data
(60) Provisional application No. 63/307,183, filed on Feb. 7, 2022.

(51) Int. Cl. H01L 25/18; H01L 23/552; H01L 23/522; H01L 23/498; H01L 23/31; H01L 23/00; H01L 25/065

(52) U.S. Cl. CPC H01L 25/18; H01L 23/552; H01L 23/5227; H01L 23/49822; H01L 23/3128; H01L 24/48; H01L 25/0657; H01L 24/32; H01L 24/73; H01L 2224/48227; H01L 2225/06562; H01L 2225/0651; H01L 2224/32145; H01L 2224/73265; H01L 2224/32225

(57) ABSTRACT

A semiconductor package assembly is provided. The semiconductor package assembly includes a base, a first system-on-chip (SOC) die, a conductive routing and a first shielding film. The first SOC die is disposed on the base. The first SOC die has a front surface and a back surface. The first SOC die includes a first inductor close to the front surface. The conductive routing is disposed on the back surface of the first SOC die. The first shielding film is disposed between the first SOC die and the conductive routing. The first shielding film covers the back surface of the first SOC die and fully overlaps the first inductor.

### CROSS REFERENCE TO RELATED APPLICATIONS

This application claims the benefit of U.S. Provisional Application No. 63/307,183, filed Feb. 7, 2022, the entirety of which is incorporated by reference herein.

### BACKGROUND OF THE INVENTION

### Field of the Invention

The present invention relates, in general, to a semiconductor package assembly, and, in particular, to a semiconductor package assembly with an external shielding feature for on-die inductors and transformers.

### Description of the Related Art

Package-on-package (PoP) assembly is an integrated circuit packaging method to combine vertically discrete system-on-chip (SOC) integrated circuits and memory packages. Two or more packages are installed on top of each other, i.e., stacked, with a standard interface to route signals between them. This allows higher component density in devices, such as mobile phones, personal digital assistants (PDA), and digital cameras.

In order to ensure the continued miniaturization and multi-functionality of electronic products and communication devices, it is desired that SOC packages be small in size, support multi-pin connection, operate at high speeds, and have high functionality. Multi-functional SOC packages include a single chip that integrates multiple functional circuits that are typically needed for a system into the single chip itself. In the design of a SOC package for radio frequency (RF) and high speed Serdes (Serializer/Deserializer) applications, however, the integrated RF digital and analog circuits cause a problem with noise coupling.

Thus, a novel semiconductor package assembly is desirable.

### BRIEF SUMMARY OF THE INVENTION

An embodiment of the present invention provides a semiconductor package assembly. The semiconductor package assembly includes a base, a first system-on-chip (SOC) die, a conductive routing and a first shielding film. The first SOC die is disposed on the base. The first SOC die has a front surface and a back surface. The first SOC die includes a first inductor close to the front surface. The conductive routing is disposed on the back surface of the first SOC die. The first shielding film is disposed between the first SOC die and the conductive routing. The first shielding film covers the back surface of the first SOC die and fully overlaps the first inductor.

An embodiment of the present invention provides a semiconductor package assembly. The semiconductor package assembly includes a base, a first system-on-chip (SOC) die, a conductive routing and a first shielding film. The first SOC die is disposed on the base. The first SOC die includes a first inductor integrated therein. The conductive routing is disposed on the first SOC die and overlaps the first inductor in a direction of a vertical projection to the first SOC die. The first shielding film is disposed between the first SOC die and the conductive routing. The first shielding film fully overlaps the first inductor in the direction of a vertical projection to the first SOC die.

An embodiment of the present invention provides a semiconductor package assembly. The semiconductor package assembly includes a base, a system-on-chip (SOC) die, a conductive routing and a shielding film. The SOC die is disposed on the base. The SOC die includes a first inductor integrated therein. The conductive routing is disposed on the SOC die and overlaps the inductor in a direction of a vertical projection to the SOC die. The conductive routing is used to transmit signals. The shielding film is disposed between the SOC die and the conductive routing. The shielding film is electrically floating and fully overlaps the inductor in the direction of a vertical projection to the SOC die.

### BRIEF DESCRIPTION OF THE DRAWINGS

The present invention can be more fully understood by reading the subsequent detailed description and examples with references made to the accompanying drawings, wherein:

FIGS. 1-8 are cross-sectional views of a semiconductor package assembly in accordance with some embodiments of the disclosure.

### DETAILED DESCRIPTION OF THE INVENTION

The following description is made for the purpose of illustrating the general principles of the invention and should not be taken in a limiting sense. The scope of the invention is best determined by reference to the appended claims.

The inventive concept is described fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the invention.

In the package-on-package (PoP) semiconductor package assembly applications, the system-on-chip (SOC) package includes one or more inductors/transformers, which are used in the RF or analog circuits such as the LC-tank phase-locked loop (PLL) circuit for high-speed 10 and RF transceiver, integrated in the SOC die. However, the on-die inductors/transformers (also serve as the victim inductors/transformers) may suffer the noise coupling problem from the signal routings (also serve as the aggressor routings) which are arranged above or below the on-die RF circuits and disposed inside or outside the SOC package. The semiconductor package assembly in accordance with some embodiments of the disclosure uses an electrically floating (or electrical grounding) shielding film to protect the victim circuits against noise interference from the aggressor routings in the vertical direction. Therefore, the noise immunity of the on-die RF/analog circuits of the SOC package is improved.

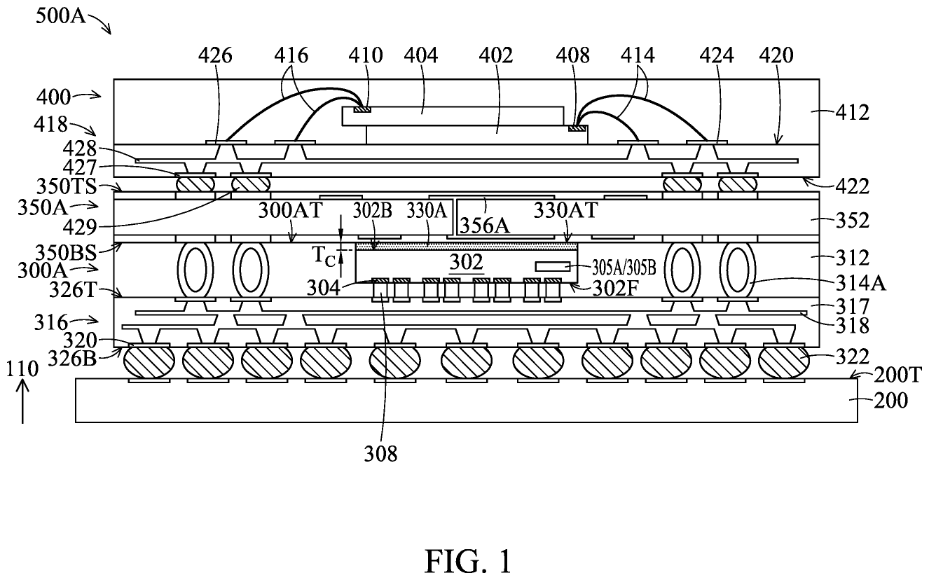

FIG. 1 is a cross-sectional view of a semiconductor package assembly 500A in accordance with some embodiments of the disclosure. In some embodiments, the semiconductor package assembly 500A is a three-dimensional (3D) package-on-package (PoP) semiconductor package assembly such as a high band package on package (HBPOP). The semiconductor package assembly 500A may include at least two vertically stacked wafer-level semiconductor packages mounted on a base 200. As shown in FIG. 1, in some embodiments, the semiconductor package assembly 500A includes the base 200, a system-on-chip (SOC) die 302, a conductive routing 356A and a shielding film 330A. In some embodiments, the semiconductor package assembly 500A further includes a system-on-chip (SOC) package 300A and a memory package 400 vertically stacked on the SOC package 300A. In addition, the SOC package 300A includes the SOC die 302, the shielding film 330A and the conductive routing 356A.

As shown in FIG. 1, the base 200, for example a printed circuit board (PCB), may be formed of polypropylene (PP). It should also be noted that the base 200 can be a single layer or a multilayer structure. A plurality of pads (not shown) and/or conductive traces (not shown) is disposed on a die-attach surface 200T of the base 200. In one embodiment, the conductive traces may comprise signal trace segments or ground trace segments, which are used for the input/output (I/O) connections of the SOC package 300A and the memory package 400. Also, the SOC package 300A is mounted directly on the conductive traces. In some other embodiments, pads are disposed on the die-attach surface 200T, connected to different terminals of the conductive traces. The pads are used for the SOC package 300A that is mounted directly on them.

As shown in FIG. 1, the SOC package 300A is mounted on the die-attach surface 200T of the base 200 by a bonding process. The SOC package 300A is mounted on the base 200 using the conductive structures 322. The SOC package 300A is a three-dimensional (3D) semiconductor package including the SOC die 302, a substrate 316 and an interposer 350A. For example, the system on chip (SOC) die 302 may include a logic die including a central processing unit (CPU), a graphic processing unit (GPU), a dynamic random access memory (DRAM) controller or any combination thereof.

As shown in FIG. 1, the SOC die 302 is disposed on a surface 326T of the substrate 316 away from the conductive structures 322. The SOC die 302 has a back surface 302B and a front surface 302F. The SOC die 302 is fabricated by a flip-chip technology. The back surface 302B of the SOC die 302 may be close to a top surface 300AT of the SOC package 300A. Pads 304 of the SOC die 302 are disposed on the front surface 302F to be electrically connected to the circuitry (not shown) of the SOC die 302. In some embodiments, the pads 304 belong to the uppermost metal layer of the interconnection structure (not shown) of the SOC die 302. The pads 304 of the SOC die 302 are in contact with the corresponding vias 308. Therefore, the SOC die 302 is connected to the substrate 316.

As shown in FIG. 1, the SOC die 302 includes one or more inductors 305A formed close to the front surface 302F. In some embodiments, the inductor 305A is integrated in the interconnection structure (not shown) of the SOC die 302. Therefore, the inductor 305A may serve as an on-die inductor 305A of the SOC die 302. The inductor 305A may be electrically connected to the pads 304 of the SOC die 302. In some other embodiments, the SOC die 302 includes a transformer 305B comprising at least two inductors 305A, which are disposed close to each other and collectively form the transformer 305B, disposed close to the front surface 302F. The transformer 305B may also serve as an on-die transformer 305B of the SOC die 302.

As shown in FIG. 1, the interposer 350A is disposed on the back surface 302B of the SOC die 302. The interposer 350A may serve as a fan-out structure for the overlying memory package 400. In some embodiments, the interposer 350A comprises a substrate 352 including a core substrate or a coreless substrate. In addition, the interposer 350A further includes one or more conductive routings 356A disposed in one or more dielectric layers (not shown). The conductive routing 356A is used to transmit signals or powers. In some embodiments, the conductive routing 356A may partially or fully overlap the inductor 305A and/or the transformer 305B of the SOC die 302 in a direction 110 of a vertical projection to the SOC die 302 (the direction 110 is vertical to the die-attach surface 200T of the base 200). In some embodiments, the conductive routings 356A may comprise conductive traces, vias and pads. The conductive routing 356A may pass through the substrate 352. In addition, the conductive routings 356A may be disposed close to a top surface 350TS and a bottom surface 350BS of the interposer 350A. However, it should be noted that the number of conductive routings 356A shown in FIG. 1 is only an example and is not a limitation to the present invention.

As shown in FIG. 1, the substrate 316 is provided for the SOC die 302 to be disposed upon. The substrate 316 is disposed on the front surface 302F of the SOC die 302 and electrically connected to the SOC die 302 via the pads 304 and the vias 308. In some embodiments, the substrate 316 includes a redistribution layer (RDL) structure having one or more conductive traces 318 disposed in one or more intermetal dielectric (IMD) layers 317. The conductive traces 318 are electrically connected to corresponding contact pads 320. The contact pads 320 are exposed to openings of the solder mask layer (not shown). In addition, the conductive structures 322 are disposed on a surface 326B of substrate 316 away from the SOC 302 and in contact with the corresponding the contact pads 320. The surface 326B of substrate 316 may serve as the bottom surface of the SOC package 300A. However, it should be noted that the number of conductive traces 318, the number of IMD layers 317 and the number of contact pads 320 shown in FIG. 1 is only an example and is not a limitation to the present invention.

As shown in FIG. 1, the SOC package 300 further includes conductive structures 322 disposed between the substrate 316 and the base 200. The conductive structures 322 are disposed on and in contact with the contact pads 320 away from the SOC die 302. In some embodiments, the conductive structures 322 may comprise a conductive bump structure such as a copper bump or a solder bump structure, a conductive pillar structure, a conductive wire structure, or a conductive paste structure.

As shown in FIG. 1, the SOC package 300A further includes a molding compound 312 disposed between the interposer 350A and the substrate 316. The molding compound 312 surrounds the SOC die 302, and fills any gaps around the SOC die 302 and between the interposer 350A and the substrate 316. The molding compound 312 is in contact with the interposer 350A, the substrate 316 and the SOC die 302. In some embodiments, the molded compound 312 may be formed of a nonconductive material, such as an epoxy, a resin, a moldable polymer, or the like. The molding compound 312 may be applied while substantially liquid, and then may be cured through a chemical reaction, such as in an epoxy or resin. In some other embodiments, the molding compound 312 may be an ultraviolet (UV) or thermally cured polymer applied as a gel or malleable solid capable of being disposed around the SOC die 302, and then may be cured using a UV or thermally curing process. The molding compound 312 may be cured with a mold.

As shown in FIG. 1, the SOC package 300A further includes conductive structures 314A passing through the molding compound 312 and electrically connected to the interposer 350A and the substrate 316, the SOC die 302 and the memory package 400. The conductive structures 314A are disposed between the interposer 350A and the substrate 316. The conductive structures 314A and the SOC die 302 may be disposed side-by-side. In addition, the conductive structures 314A may be disposed as an array along parallel edges (not shown) of the SOC package 300A. Therefore, the SOC die 302 is disposed between the conductive structures 314A. In some embodiments, the conductive structures 314A may comprise a conductive ball structure such as a copper ball, a conductive bump structure such as a copper bump or a solder bump structure, or a conductive pillar structure such as a copper pillar structure.

As shown in FIG. 1, the memory package 400 is stacked on the SOC package 300A by a bonding process. In some embodiments, the memory package 400 comprises a dynamic random access memory (DRAM) package or another applicable memory package. In some embodiments, the memory package 400 includes a memory package substrate 418, conductive structures 429 and at least one memory die, for example, two memory dies 402 and 404 that are stacked on the memory package substrate 418. In some embodiments, the memory dies 402 and 404 comprises a dynamic random access memory (DRAM) die or another applicable memory die. The memory package substrate 418 has a top surface 420 and a bottom surface 422. For example, the top surface 420 may serve as a die-attach surface 420, and the bottom surface 422 may serve as a bump-attach surface 422 opposite the die-attach surface 420. In this embodiment, as shown in FIG. 1, there are two memory dies 402 and 404 mounted on the top surface (die-attach surface) 420 of the memory package substrate 418. The memory die 404 having a pad 410 is stacked on the memory die 402 having a pad 408 using a paste (not shown), and the memory die 402 is mounted on die-attach surface 420 of the memory package substrate 418 by a paste (not shown). The memory dies 402 and 404 may be electrically connected to the memory package substrate 418 using conductive structures, for example, bonding wires 414 and 416, connected to the pads 408 and 410. In some other embodiments, the memory dies 402 and 404 are electrically connected to the memory package substrate 418 using other applicable conductive structures, for example, conductive bump structures (such as a copper bump or a solder bump structure), conductive pillar structures, or a conductive paste structure. However, the number of stacked memory dies is not limited to the disclosed embodiment. Alternatively, the memory dies 402 and 404 as shown in FIG. 1 can be arranged side by side. Therefore, the memory dies 402 and 404 are mounted on the top surface (die-attach surface) 420 of the memory package substrate 418 by paste.

As shown in FIG. 1, the memory package substrate 418 may comprise a circuitry 428 and metal pads 424 and 426 and 427. The metal pads 424 and 426 are disposed on the top of the circuitry 428 close to the top surface (die-attach surface) 420. The metal pads 427 are disposed on the bottom of the circuitry 428 close to the bottom surface (bump-attach surface) 422 of the memory package substrate 418. The circuitry 428 of the memory package 400 is interconnected to the conductive routings 356A of the interposer 350A via the conductive structures 429 disposed on the bottom surface (bump-attach surface) 422 of the memory package substrate 418. In some embodiments, the conductive structures 429 of the memory package 400 are electrically connected to the conductive traces 318 of the substrate 316 of the SOC package 300A by the conductive routings 356A of the interposer 350A and the conductive structures 314A passing through the molding compound 312 between the memory package 400 and the substrate 316 of the SOC package 300A. In some embodiments, the conductive structures 429 may comprise a conductive bump structure such as a copper bump or a solder bump structure, a conductive pillar structure, or a conductive paste structure.

In some embodiments, as shown in FIG. 1, the memory package 400 further includes a molding material 412 covering the top surface 420 of the memory package substrate 418, encapsulating the memory dies 402 and 404 and the bonding wires 414 and 416. The molding materials 312 and 412 may comprise the same or similar materials and fabrication processes.

As shown in FIG. 1, the shielding film 330A of the semiconductor package assembly 500A is disposed between the SOC die 302 and the conductive routing 356A of the interposer 350A. In some embodiments, the shielding film 330A is surrounded by the molding compound 312. In addition, the shielding film 330A may be electrically isolated from the conductive structures 314A. Alternatively, the shielding film 330A may be electrically connected to the conductive structures 314A by some routings (not shown) of the interposer 350A which are electrically connected to a ground (GND) terminal (not shown). The shielding film 330A is in contact with the back surface 302B of the SOC die 302 and fully overlaps the inductor 305A (or the transformer 305B) in the direction 110 of a vertical projection to the SOC die 302 (also serve as the vertical direction 110). In addition, a top surface 330AT of the shielding film 330A may level with (FIG. 1) or lower than the top surface 300AT of the SOC package 300A. In some embodiments, the shielding film 330A is used to shield the inductor 305A (or the transformer 305B) to minimize the coupling from the noise source (the signal or power routings such as the conductive routing 356A of the interposer 350A). The shielding film 330A may overlap the conductive routing 356A of the interposer 350A in the vertical direction 110. In some embodiments, the shielding film 330A fully covers the back surface 302B of the SOC die 302. In some other embodiments, the shielding film 330A partially covers the back surface 302B of the SOC die 302 and fully overlaps the inductor 305A of the SOC die 302. In some embodiments, the shielding film 330A is electrically floating. Alternatively, the shielding film 330A is electrically connected to a ground (GND) terminal (not shown).

As shown in FIG. 1, the shielding film 330A has a thickness Tc in the vertical direction 110. In some embodiments, the minimum value of the thickness Tc of the shielding film 330A depends on the electrical conductivity of the shielding film 330A and the operation frequency of a circuit using the inductor 305A in the SOC die 302 to achieve at least 10 dB noise coupling reduction from an aggressor to the inductor 305A (or the transformer 305B). That is, the thickness Tc of the shielding film 330A should be greater than the skin depth of the shielding film 330A

$$( the skin depth = \frac{1}{\sqrt{π f μ σ}} ,$$

where σ is the electrical conductivity of the shielding film 330A (for example, a conductive dielectric film, σ≈2×10⁵ S/m), f is the frequency of the circuit using the inductor 305A in Hz, μ is the permeability of the shielding film 330A). In some embodiments, the shielding film 330A could be a conductive dielectric film, a metal coating, a metal plane or another applicable shielding film. For example, the conductive dielectric film may be formed of a compound including dielectric and metal particles. In some embodiments, the shielding film 330A could also be non-conductive dielectric film.

In some embodiments, the semiconductor package assembly 500A includes the memory package 400 vertically stacked on the SOC package 300A having the interposer 350A between the SOC die 302 and the memory dies 402 and 404. The on-die inductor 305A (or the transformer 305B) as a victim integrated in the SOC die 302 may suffer a coupling spur fatal issue resulting from aggressors (e.g., the conductive routing 356A of the interposer 350A) above the SOC die 302, which can be regarded as a coupling issue due to aggressor routings in the direction 110 of a vertical projection to the SOC die 302 (also serve as the vertical direction 110). To solve the aforementioned problem, the semiconductor package assembly 500A uses the electrically floating (or electrical grounding) conductive film 330A interposed between the victim, that is, on-die inductor 305A (or the transformer 305B) of the SOC die 302 and the interposer 350A having the aggressor routings (e.g., the conductive routing 356A) in the direction 110 of a vertical projection to the SOC die 302 to minimize the coupling issue.

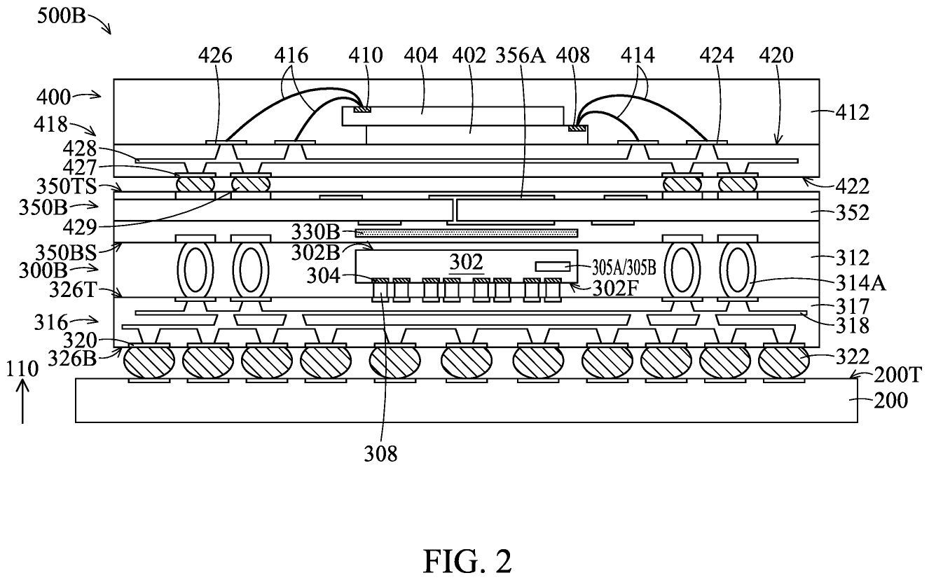

FIG. 2 is a cross-sectional view of a semiconductor package assembly 500B in accordance with some embodiments of the disclosure. Elements of the embodiments hereinafter, that are the same or similar as those previously described with reference to FIG. 1 are not repeated for brevity. In some embodiments, the shielding film used to shield the on-die inductor/transformer can be formed in the interposer. The difference between the semiconductor package assembly 500A and the semiconductor package assembly 500B is that the semiconductor package assembly 500B includes a shielding film 330B formed in an interposer 350B of a SOC package 300B. In some embodiments, the shielding film 330B is formed as a conductive plane in the interposer 350B and disposed between the SOC die 302 and the conductive routing 356A of the interposer 350B in the direction 110 of a vertical projection to the SOC die 302. In addition, the shielding film 330B fully overlaps the inductor 305A (or the transformer 305B) in the direction 110 of a vertical projection to the SOC die 302. The shielding film 330B may overlap the conductive routing 356A of the interposer 350B in the vertical direction 110. In some embodiments as shown in FIG. 2, the shielding film 330B fully covers the back surface 302B of the SOC die 302. In some other embodiments, the shielding film 330B partially covers the back surface 302B of the SOC die 302 and fully overlaps the inductor 305A of the SOC die 302. In some embodiments, the shielding film 330B is electrically floating. Alternatively, the shielding film 330B is electrically connected to a GND terminal. In some embodiments, the shielding films 330A and 330B may comprise the same or similar materials and compositions.

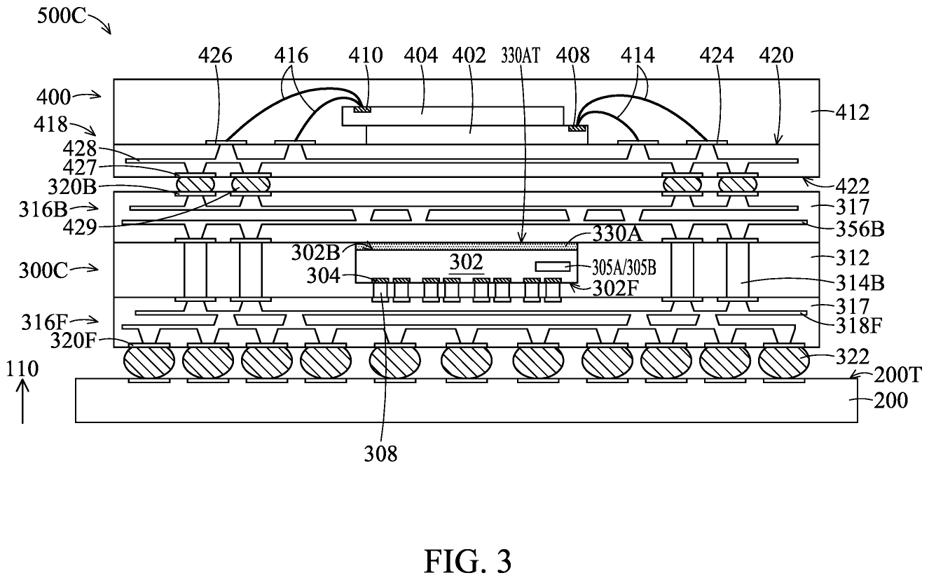

FIG. 3 is a cross-sectional view of a semiconductor package assembly 500C in accordance with some embodiments of the disclosure. Elements of the embodiments hereinafter, that are the same or similar as those previously described with reference to FIGS. 1 and 2 are not repeated for brevity. In some embodiments, the shielding film may be applied in the three-dimensional (3D) package-on-package (PoP) semiconductor package assembly including a back-side redistribution layer (RDL) structure and a front-side redistribution layer (RDL) structure. The shielding film may be disposed between the back-side redistribution layer (RDL) structure and the on-die inductor (or the transformer 305B) integrated in the SOC die to minimize the coupling issue from the conductive routings in the back-side RDL structure. The difference between the semiconductor package assembly 500A and the semiconductor package assembly 500C is that the semiconductor package assembly 500C includes a SOC package 300C including through via (TV) interconnects 314B, a back-side redistribution layer (RDL) structure 316B and a front-side redistribution layer (RDL) structure 316F. The back-side RDL structure 316B is disposed on the back surface 302B of the SOC die 302. The TV interconnects 314B pass through the molding compound. The TV interconnects 314B are disposed between and electrically connected to the back-side RDL structure 316B and the front-side RDL structure 316F. In some embodiments, the back-side RDL structure 316B includes one or more conductive routings 356B (the noise source) disposed in one or more intermetal dielectric (IMD) layers 317 for transmitting signals or powers. The conductive routing 356B is electrically connected to corresponding RDL contact pads 320B. The front-side RDL structure 316F is disposed on the front surface 302F of the SOC die 302. The front-side RDL structure 316F is electrically connected to the pads 304 of the SOC die 302 by the vias 308. In some embodiments, the front-side RDL structure 316F may have one or more conductive traces 318F disposed in one or more intermetal dielectric (IMD) layers 317. The conductive traces 318F are electrically connected to corresponding RDL contact pads 320F. The RDL contact pads 320F and 320B are exposed to openings of corresponding solder mask layers (not shown). However, it should be noted that the number of conductive routings 356B, the number of conductive traces 318F, the number of IMD layers 317 and the number of RDL contact pads 320F and 320B shown in FIG. 3 is only an example and is not a limitation to the present invention.

As shown in FIG. 3, the shielding film 330A of the semiconductor package assembly 500C is disposed between the SOC die 302 and the conductive routing 356B of the back-side RDL structure 316B. The shielding film 330A may be in contact with the back surface 302B of the SOC die 302 and the back-side RDL structure 316B. In addition, the shielding film 330A fully overlaps the inductor 305A (or the transformer 305B) in the direction 110 of a vertical projection to the SOC die 302 (also serve as the vertical direction 110). In some embodiments, the shielding film 330A is used to shield the inductor 305A (or the transformer 305B) to minimize the coupling from the noise source (the signal or power routings such as the conductive routing 356B of the back-side RDL structure 316B). The shielding film 330A may overlap the conductive routing 356B of the back-side RDL structure 316B in the vertical direction 110.

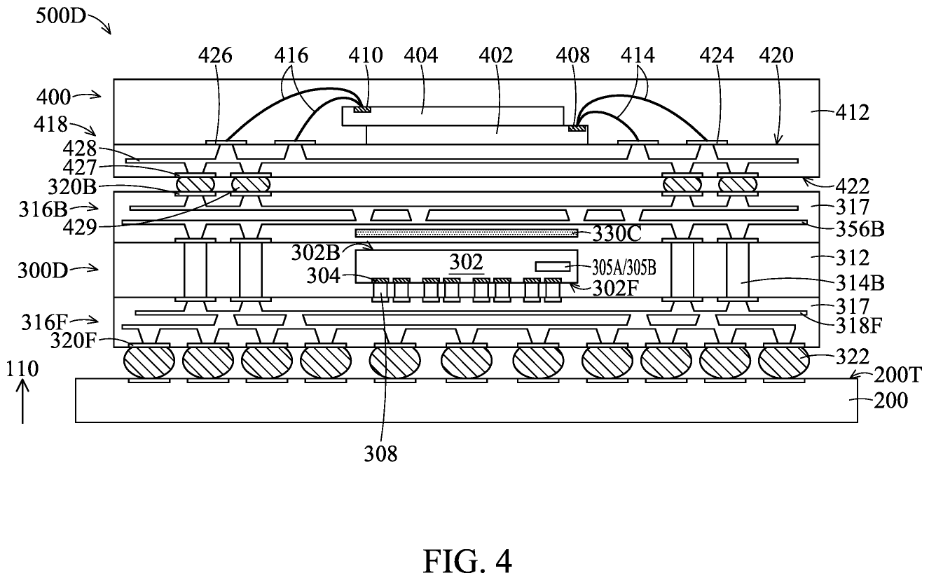

FIG. 4 is a cross-sectional view of a semiconductor package assembly 500D in accordance with some embodiments of the disclosure. Elements of the embodiments hereinafter, that are the same or similar as those previously described with reference to FIGS. 1-3 are not repeated for brevity. In some embodiments, the shielding film used to shield the on-die inductor/transformer can be formed in the back-side RDL structure as an RDL plane. The difference between the semiconductor package assembly 500C and the semiconductor package assembly 500D is that the semiconductor package assembly 500D includes a SOC package 300D including a shielding film 330C formed in the back-side RDL structure 316B. In some embodiments, the shielding film 330C is formed as an RDL plane in the back-side RDL structure 316B and disposed between the SOC die 302 and the conductive routing 356B of the back-side RDL structure 316B in the direction 110 of a vertical projection to the SOC die 302. In addition, the shielding film 330C fully overlaps the inductor 305A (or the transformer 305B) in the direction 110 of a vertical projection to the SOC die 302. The shielding film 330C may overlap the conductive routing 356B of the back-side RDL structure 316B in the vertical direction 110. In some embodiments as shown in FIG. 4, the shielding film 330C fully covers the back surface 302B of the SOC die 302 in the vertical direction 110. In some other embodiments, the shielding film 330C partially covers the back surface 302B of the SOC die 302 and fully overlaps the inductor 305A/transformer 305B of the SOC die 302. In some embodiments, the shielding film 330C is electrically floating. Alternatively, the shielding film 330C is electrically connected to a GND terminal. In some embodiments, the shielding films 330A, 330B and 330C may comprise the same or similar materials and compositions.

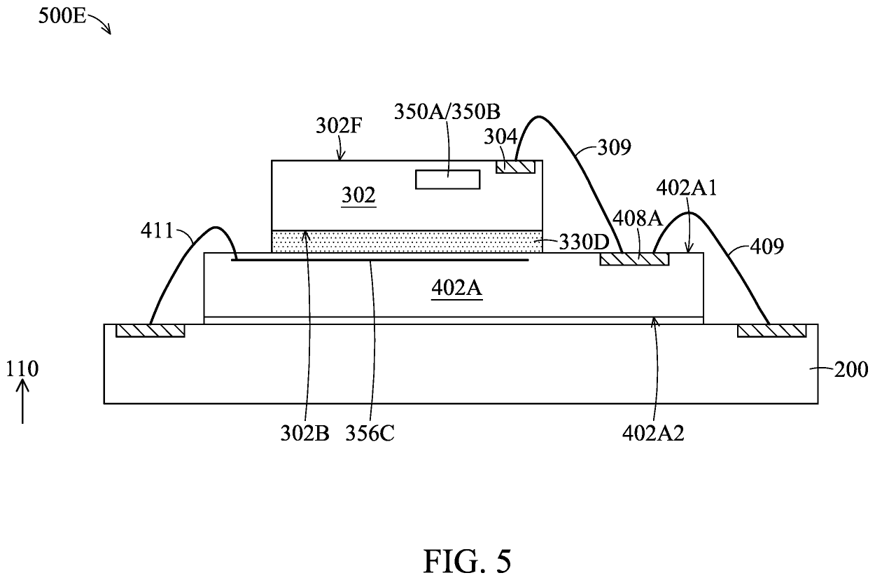

FIG. 5 is a cross-sectional view of a semiconductor package assembly 500E in accordance with some embodiments of the disclosure. Elements of the embodiments hereinafter, that are the same or similar as those previously described with reference to FIGS. 1-4 are not repeated for brevity. In some embodiments, the shielding film may be applied in the three-dimensional (3D) package-on-package (PoP) semiconductor package assembly including a SOC die vertically stacked on an aggressor die (e.g., the memory die or another SOC die having the aggressor routings) and electrically connected to the base using the wire bonding technology. The floating/grounding shielding film may be disposed between the on-die inductor (or the transformer) and the aggressor die to minimize the coupling issue from the conductive routings in the aggressor die.

As shown in FIG. 5, the semiconductor package assembly 500E is a three-dimensional (3D) package-on-package (PoP) semiconductor package assembly using the wire bonding technology. The semiconductor package assembly 500E may include at least two vertically stacked semiconductor dies mounted on the base 200 and electrically connected to the base 200 using bonding wires. As shown in FIG. 5, in some embodiments, the semiconductor package assembly 500E includes the base 200, the system-on-chip (SOC) die 302, an aggressor die 402A and a shielding film 330D. In some embodiments, the SOC die 302 is vertically stacked on the aggressor die 402A. In other words, the aggressor die 402A is disposed between the SOC die 302 and the base 200 in the direction 110 of a vertical projection to the SOC die 302. In some embodiments, the aggressor die 402A comprises a memory die or another SOC die. The SOC die 302 includes the pad 304 close to the front surface 302F. The aggressor die 402A has a surface 402A1 close to the SOC die 302 and a surface 402A2 close to the base 200. The aggressor die 402A may be mounted on the base 200 by paste. In addition, the aggressor die 402A includes a pad 408A close to the surface 402A1 of the aggressor die 402A. In some embodiments, the aggressor die 402A includes a conductive routing 356C close to the surface 402A1 for transmitting signals or powers. As shown in FIG. 5, the SOC die 302 may be electrically connected to the pad 408A of the aggressor die 402A using a bonding wire 309 connected to the pad 304. The aggressor die 402A may be electrically connected to the base 200 using bonding wires 409 and 411 connected to the pad 408A and the conductive routing 356C. In other words, the SOC die 302 may be electrically connected to the base 200 using the bonding wires 309 and 409. However, the number of stacked SOC die and aggressor die is not limited to the disclosed embodiment.

In some embodiments, the shielding film 330D of the semiconductor package assembly 500E is disposed between the SOC die 302 and the conductive routing 356C of the aggressor die 402A in the direction 110 of a vertical projection to the SOC die 302. In some embodiments, the shielding film 330D is electrically isolated from the SOC die 302 and the aggressor die 402A. The shielding film 330D may be in contact with the back surface 302B of the SOC die 302 and fully overlap the inductor 305A (or the transformer 305B) in the direction 110 of a vertical projection to the SOC die 302 (the vertical direction 110). In some embodiments, the shielding film 330D is used to shield the inductor 305A (or the transformer 305B) to minimize the coupling from the noise source (the signal or power routings such as the conductive routing 356C of the aggressor die 402A) below the SOC die 302. The shielding film 330D may overlap the conductive routing 356C of the aggressor die 402A in the vertical direction 110. In some embodiments as shown in FIG. 5, the shielding film 330D fully covers the back surface 302B of the SOC die 302. In some other embodiments, the shielding film 330D partially covers the back surface 302B of the SOC die 302 and fully overlaps the inductor 305A (or the transformer 305B) of the SOC die 302. In some embodiments, the shielding film 330D is electrically floating. Alternatively, the shielding film 330D is electrically connected to a GND terminal. In some embodiments, the shielding films 330A, 330B, 330C and 330D may comprise the same or similar materials and compositions.

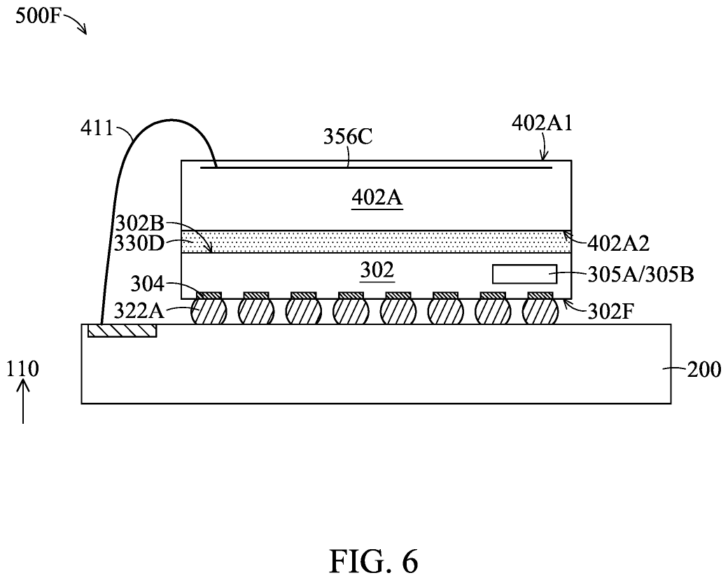

FIG. 6 is a cross-sectional view of a semiconductor package assembly 500F in accordance with some embodiments of the disclosure. Elements of the embodiments hereinafter, that are the same or similar as those previously described with reference to FIGS. 1-5 are not repeated for brevity. In some embodiments, the shielding film may be applied in the three-dimensional (3D) package-on-package (PoP) semiconductor package assembly including vertically an aggressor die (e.g., the memory die or another SOC die including the aggressor routings) stacked on a SOC die. In addition, the aggressor die may be electrically connected to the base using the wire bonding technology. The SOC die may be mounted on the base and electrically connected to the base using conductive structures. The floating/grounding shielding film may be disposed between the on-die inductor (or the transformer) integrated in the SOC die and the aggressor die to minimize the coupling issue from the conductive routings in the aggressor die.

As shown in FIG. 6, the difference between the semiconductor package assembly 500E and the semiconductor package assembly 500F is that the semiconductor package assembly 500F includes the SOC die 302 disposed between the aggressor die 402A and the base 200 in the direction 110 of a vertical projection to the SOC die 302. The front surface 302F of the SOC die 302 is close to base 200 and the back surface 302A of the SOC die 302 close to the aggressor die 402A. The SOC die 302 is mounted on and electrically connected to the base 200 using conductive structures 322A. The conductive structures 322A are disposed on the front surface 302F and electrically connected to the pads 304 of the SOC die 302. In some embodiments, the conductive structures 322 (FIGS. 1-4) and the conductive structures 322A may comprise the same or similar structures. As shown in FIG. 6, the surface 402A1 of the aggressor die 402A is away from the SOC die 302. The surface 402A2 of the aggressor die 402A is close to the SOC die 302. The aggressor die 402A may be electrically connected to the base 200 using bonding wire 411 connected to the conductive routing 356C.

In some embodiments, the shielding film 330D of the semiconductor package assembly 500F is disposed between the SOC die 302 and the conductive routing 356C of the aggressor die 402A. In some embodiments, the shielding film 330A is surrounded by the molding compound 312. The shielding film 330D may be in contact with the back surface 302B of the SOC die 302 and the surface 402A2 of the aggressor die 402A. In addition, the shielding film 330D may fully overlap the inductor 305A (or the transformer 305B) in the direction 110 of a vertical projection to the SOC die 302 (also serve as the vertical direction 110). In some embodiments, the shielding film 330D is used to shield the inductor 305A (or the transformer 305B) to minimize the coupling from the noise source (the signal or power routings such as the conductive routing 356C of the aggressor die 402A) above the SOC die 302.

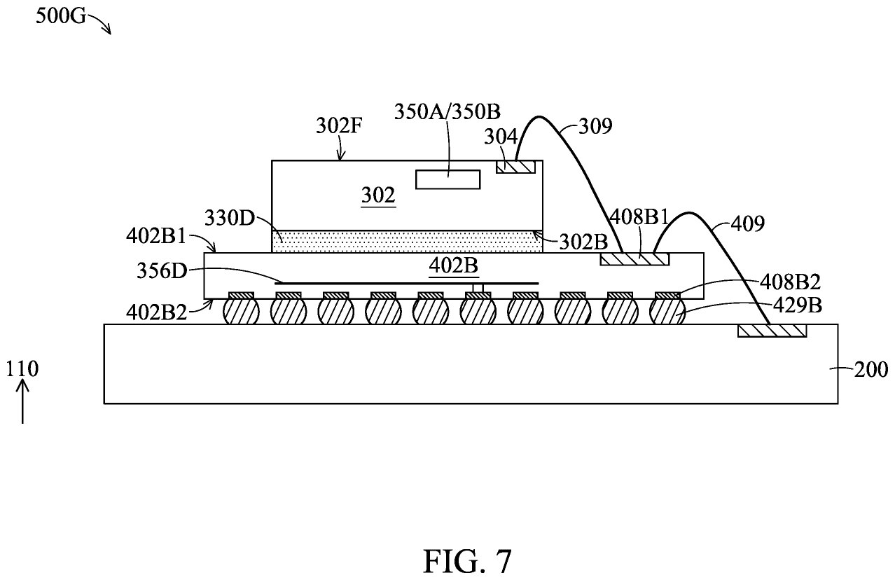

FIG. 7 is a cross-sectional view of a semiconductor package assembly 500G in accordance with some embodiments of the disclosure. Elements of the embodiments hereinafter, that are the same or similar as those previously described with reference to FIGS. 1-6 are not repeated for brevity. In some embodiments, the shielding film may be applied in the three-dimensional (3D) package-on-package (PoP) semiconductor package assembly including a SOC die vertically stacked on an aggressor die (e.g., the memory die or another SOC die including the aggressor routings). The SOC die may be electrically connected to the base using the wire bonding technology. In addition, the aggressor die may be mounted on the base and electrically connected to the base using both bonding wires and conductive structures. The floating/grounding shielding film may be disposed between the on-die inductor (or the transformer) integrated in the SOC die and the underlying aggressor die to minimize the coupling issue from the conductive routings in the aggressor die.

As shown in FIG. 7, the difference between the semiconductor package assembly 500E and the semiconductor package assembly 500G is that the semiconductor package assembly 500G includes an aggressor die 402B disposed between the SOC die 302 and the base 200 in the direction 110 of a vertical projection to the SOC die 302. The aggressor die 402B has opposite surfaces 402B1 and 402B2 close to the aggressor die 402A and the base 200. The aggressor die 402B includes pads 408B1 and 408B2 close to the surfaces 402B1 and 402B2. The SOC die 302 is electrically connected to the pad 408B1 of the aggressor die 402B using the bonding wire 309. In addition, the aggressor die 402B is mounted on the base 200 and electrically connected to the base 200 using both the bonding wire 409 and conductive structures 429B. The bonding wire 409 is electrically connected to the pad 408B. The conductive structures 429B are disposed on the surface 402B2 and electrically connected to the pads 408B2. In some embodiments, the conductive structures 429 and 429B may comprise the same or similar structures.

In some embodiments, the aggressor die 402B includes a conductive routing 356D close to the surface 402B2. As shown in FIG. 7, the conductive routing 356D may be electrically connected to the pads 408B2 and the conductive structures 429B for transmitting signals and powers. In addition, the conductive routing 356D may overlap the inductor 305A (or the transformer 305B) integrated in the SOC die 302 in the direction 110 of a vertical projection to the SOC die 302. In some other embodiments, the conductive routing 356D may be disposed close to the surface 402B1 and electrically connected to the pad 408B.

In some embodiments, the shielding film 330D of the semiconductor package assembly 500G is disposed between the SOC die 302 and the conductive routing 356D of the aggressor die 402B in the direction 110 of a vertical projection to the SOC die 302. In some embodiments, the shielding film 330D is in contact with the back surface 302B of the SOC die 302 and the surface 402B2 of the aggressor die 402B. In addition, the shielding film 330D fully overlaps the inductor 305A (or the transformer 305B) in the direction 110 of a vertical projection to the SOC die 302 (the vertical direction 110). In some embodiments, the floating/grounding shielding film 330D is used to shield the inductor 305A (or the transformer 305B) to minimize the coupling from the noise source (the signal or power routings such as the conductive routing 356D of the aggressor die 402B) below the SOC die 302.

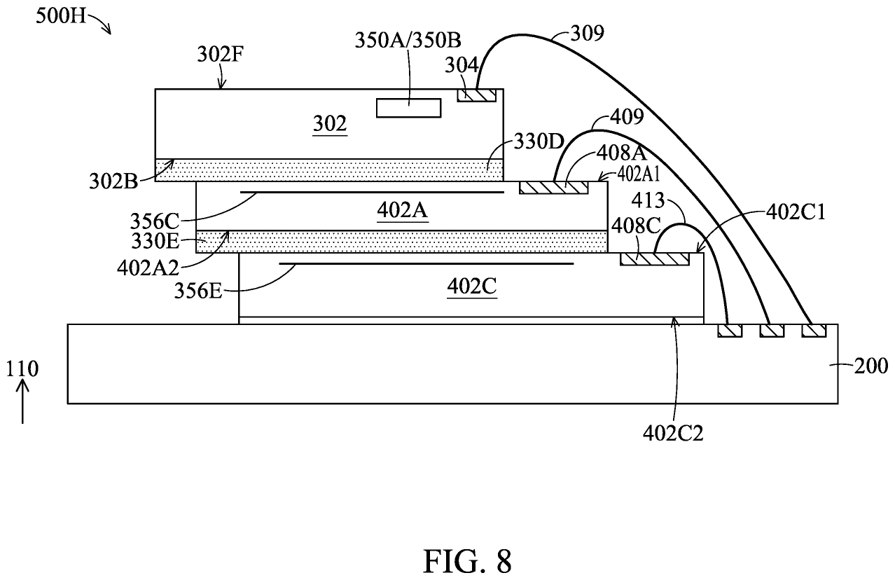

FIG. 8 is a cross-sectional view of a semiconductor package assembly 500H in accordance with some embodiments of the disclosure. Elements of the embodiments hereinafter, that are the same or similar as those previously described with reference to FIGS. 1-6 are not repeated for brevity. In some embodiments, the shielding film may be applied in the three-dimensional (3D) package-on-package (PoP) semiconductor package assembly including a SOC die vertically stacked on multi aggressor dies (e.g., the memory die, the other SOC die or a combination thereof). The SOC die may be electrically connected to the base using the wire bonding technology. In addition, the vertically stacked aggressor dies may be mounted on the base and electrically connected to the base using the wire bonding technology. The floating/grounding shielding film may be disposed between the on-die inductor (or the transformer) integrated in the SOC die and the underlying aggressor die to minimize the coupling issue from the conductive routings in the aggressor die. Optionally, an additional floating/grounding shielding film may be disposed between the stacked aggressor dies to further minimize the coupling issue from the conductive routings in the vertically stacked aggressor dies.

As shown in FIG. 8, the difference between the semiconductor package assembly 500E and the semiconductor package assembly 500H is that the semiconductor package assembly 500H further includes an aggressor die 402C and a shielding film 330E. The aggressor die 402C mounted on the base 200 and the aggressor die 402A stacked on the aggressor die 402C in the direction 110 of a vertical projection to the SOC die 302. In addition, the SOC die 302 is stacked on the aggressor dies 402A and 402C in the direction 110 of a vertical projection to the SOC die 302. In addition, the aggressor die 402A has opposite surfaces 402A1 and 402A2 close to SOC die 302 and the aggressor die 402C. The aggressor die 402A includes the pad 408A close to the surface 402A1. Furthermore, the aggressor die 402C has opposite surfaces 402C1 and 402C2 close to aggressor die 402A and the base 200. The aggressor die 402C includes a pad 408C close to the surface 402C1. The pad 304 of the SOC die 302, the pad 408A of the aggressor die 402A and the pad 408C of the aggressor die 402C are electrically connected to the base 200 using the bonding wires 309, 409 and 413.

In some embodiments, the floating/grounding shielding film 330D overlaps the conductive routing 356C of the aggressor die 402A and a conductive routing 356E of the aggressor die 402C. In addition, the shielding film 330D fully overlaps the inductor 305A (or the transformer 305B) of the SOC die 302 in the direction 110 of a vertical projection to the SOC die 302 (the vertical direction 110). In some embodiments, the shielding film 330E is optionally disposed between the aggressor dies 402A and 402C. The shielding film 330E may be in contact with both the surface 402A2 of the aggressor die 402A and the surface 402C1 of the aggressor die 402C. In addition, the shielding film 330E overlaps a conductive routing 356E of the aggressor die 402C and fully overlaps the inductor 305A (or the transformer 305B) of the SOC die 302 in the direction 110 of a vertical projection to the SOC die 302 (also serve as the vertical direction 110). In some embodiments, the shielding film 330D is electrically floating. Alternatively, the shielding film 330D is electrically connected to a GND terminal. In some embodiments as shown in FIG. 8, the shielding film 330D is a conductive film and the shielding film 330E is a conductive film or a non-conductive dielectric film. When the shielding film 330E is a conductive film, the shielding film 330E could be electrically floating or electrically connected to a GND terminal. Besides the shielding film 330D, the floating/grounding shielding film 330E is optionally used to shield the on-chip inductor 305A (or the transformer 305B) to further minimize the coupling from the noise source (the signal or powers routings such as the conductive routing 356E of the aggressor die 402C) below the SOC die 302.

Embodiments provide a semiconductor package assembly, for example, a three-dimensional (3D) package-on-package (PoP) semiconductor package assembly. The semiconductor package assembly includes an on-die inductor/transformer (also serve as the victim inductor/transformer) integrated in the SOC die and a signal routing (also serve as the aggressor routing) disposed above or below the SOC die. In addition, the aggressor routing may be disposed inside or outside the SOC package. The semiconductor package assembly uses the electrically floating/grounding shielding film interposed between the victim inductor/transformer of the SOC die and the aggressor routing in the direction of a vertical projection to the SOC die to minimize the coupling issue from the aggressor routing. In some embodiments, the electrically floating (or electrical grounding) shielding film covers the SOC die and fully overlaps the victim inductor/transformer. In some embodiments, the electrically floating/grounding shielding film is formed as an external shielding feature to the SOC die. In some embodiments, the electrically floating/grounding shielding film is integrated in the interposer or the back-side RDL structure of the SOC package. Therefore, the noise immunity of the on-die victim circuits using the inductor and the transformer in the SOC package is improved. In more detail, the coupling noise of the victim inductor/transformer will be reduced over 20 dB by the arrangements of the electrically floating (or electrical grounding) shielding film.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package assembly, comprising:
a base;
a first system-on-chip (SOC) die disposed on the base and having a front surface and a back surface, wherein the first SOC die comprises a first inductor close to the front surface;
a conductive routing disposed on the back surface of the first SOC die; and
a first shielding film disposed between the first SOC die and the conductive routing, wherein the first shielding film covers the back surface of the first SOC die and fully overlaps the first inductor.

2. The semiconductor package assembly as claimed in claim 1, wherein the first shielding film is electrically floating.

3. The semiconductor package assembly as claimed in claim 1, wherein the shielding film is electrically connected to a ground (GND) terminal.

4. The semiconductor package assembly as claimed in claim 1, wherein the first shielding film overlaps the conductive routing.

5. The semiconductor package assembly as claimed in claim 1, wherein the conductive routing overlaps the first inductor.

6. The semiconductor package assembly as claimed in claim 1, wherein the first shielding film fully covers the back surface of the first SOC die.

7. The semiconductor package assembly as claimed in claim 1, wherein the first shielding film partially covers the back surface of the first SOC die.

8. The semiconductor package assembly as claimed in claim 1, wherein the first SOC die further comprises a second inductor close to the first inductor and disposed close to the front surface, wherein the first inductor and the second inductor collectively form a transformer.

9. The semiconductor package assembly as claimed in claim 1, wherein the first SOC die and the conductive routing are included in a first system-on-chip (SOC) package.

10. The semiconductor package assembly as claimed in claim 9, wherein the first SOC package further comprises:
an interposer disposed on the back surface of the first SOC die, wherein the interposer comprises the conductive routing; and
a first substrate disposed on the front surface of the first SOC die and electrically connected to pads of the first SOC die, wherein the pads are disposed on the front surface of the first SOC die.

11. The semiconductor package assembly as claimed in claim 10, wherein the first shielding film is formed as a conductive plane in the interposer.

12. The semiconductor package assembly as claimed in claim 9, wherein the first SOC package further comprises:
a back-side redistribution layer (RDL) structure disposed on the back surface of the first SOC die, wherein the back-side RDL structure comprises the conductive routing; and
a front-side redistribution layer (RDL) structure disposed on the front surface of the first SOC die and electrically connected to pads of the first SOC die, wherein the pads are disposed on the front surface of the first SOC die.

13. The semiconductor package assembly as claimed in claim 12, wherein the first shielding film is formed as an RDL plane of the back-side RDL structure.

14. The semiconductor package assembly as claimed in claim 9, wherein the first SOC package further comprises:
a molding compound surrounding and in contact with the first shielding film and the first SOC die; and
first conductive structures passing through the molding compound and electrically connected to the conductive routing, wherein the first shielding film is isolated from the first conductive structures.

15. The semiconductor package assembly as claimed in claim 1, further comprising:
a second die stacked on the first SOC die, wherein the second die comprises the conductive routing.

16. The semiconductor package assembly as claimed in claim 15, wherein the second die comprises a memory die or a second SOC die.

17. The semiconductor package assembly as claimed in claim 15, wherein the first SOC die is disposed between the second die and the base.

18. The semiconductor package assembly as claimed in claim 15, wherein the second die is disposed between the first SOC die and the base.

19. The semiconductor package assembly as claimed in claim 15, wherein the second die is electrically connected to the base using bonding wires.

20. The semiconductor package assembly as claimed in claim 19, wherein the first SOC die is electrically connected to the base using bonding wires.

21. The semiconductor package assembly as claimed in claim 15, wherein the second die is included in a second package.

22. The semiconductor package assembly as claimed in claim 21, wherein the second package comprises:
a second substrate having a top surface and a bottom surface, wherein the second die is mounted on the top surface of the second substrate and electrically connected to the second substrate; and
second conductive structures in contact with the bottom surface of the second substrate and electrically connected to the first SOC die and the base.

23. The semiconductor package assembly as claimed in claim 15, further comprising:
a third die stacked on the second die; and
a second shielding film between the second die and the third die, wherein the second shielding film is electrically floating or electrically connected to a ground (GND) terminal, and wherein the second shielding film fully overlaps the first inductor.

24. A semiconductor package assembly, comprising:
a base;
a first system-on-chip (SOC) die disposed on the base and comprising a first inductor integrated therein;
a conductive routing disposed on the first SOC die and overlapping the first inductor in a direction of a vertical projection to the first SOC die; and
a first shielding film disposed between the first SOC die and the conductive routing, wherein the first shielding film fully overlaps the first inductor in the direction of a vertical projection to the first SOC die.

25. The semiconductor package assembly as claimed in claim 24, wherein the first shielding film is electrically floating or electrically connected to a ground (GND) terminal.

26. The semiconductor package assembly as claimed in claim 24, wherein the first shielding film overlaps the conductive routing.

27. The semiconductor package assembly as claimed in claim 24, wherein the first SOC die comprises a transformer composed of the first inductor and a second inductor, wherein the first shielding film fully overlaps the transformer in the direction of a vertical projection to the first SOC die.

28. The semiconductor package assembly as claimed in claim 24, further comprising:
a first SOC package, comprising:
the first SOC die having a front surface and a back surface;
an interposer disposed on the back surface of the first SOC die, wherein the interposer comprises the conductive routing; and
a first substrate disposed on the front surface of the first SOC die and electrically connected to pads of the first SOC die, wherein the pads are close to the first inductor.

29. The semiconductor package assembly as claimed in claim 28, wherein the first shielding film is formed as a conductive plane in the interposer.

30. The semiconductor package assembly as claimed in claim 24, further comprising:
a first SOC package, comprising:
the first SOC die having a front surface and a back surface;
a back-side redistribution layer (RDL) structure disposed on the back surface of the first SOC die, wherein the back-side RDL structure comprises the conductive routing; and
a front-side redistribution layer (RDL) structure disposed on the front surface of the first SOC die and electrically connected to pads of the first SOC die, wherein the pads are close to the first inductor.

31. The semiconductor package assembly as claimed in claim 30, wherein the first shielding film is an RDL plane of the back-side RDL structure.

32. The semiconductor package assembly as claimed in claim 24, further comprising:
a second die stacked on the first SOC die and in contact with the first shielding film, wherein the second die comprises the conductive routing.

33. The semiconductor package assembly as claimed in claim 32, wherein the second die comprises a memory die or a second SOC die.

34. The semiconductor package assembly as claimed in claim 32, further comprising:
a second package, comprising:
the second die;
a second substrate having a top surface and a bottom surface, wherein the second die is mounted on the top surface of the second substrate and electrically connected to the second substrate; and
second conductive structures in contact with the bottom surface of the second substrate and electrically connected to the first SOC die and the base.

35. The semiconductor package assembly as claimed in claim 32, further comprising:
a third die stacked on the second die; and
a second shielding film between the second die and the third die, wherein the second shielding film is electrically floating or electrically connected to a ground (GND) terminal, and wherein the second shielding film fully overlaps the first inductor in the direction of a vertical projection to the first SOC die.

36. A semiconductor package assembly, comprising:
a base;
a system-on-chip (SOC) die disposed on the base and comprising an inductor integrated therein;
a conductive routing disposed on the SOC die and overlapping the inductor in a direction of a vertical projection to the SOC die, wherein the conductive routing is used to transmit signals; and
a shielding film disposed between the SOC die and the conductive routing, wherein the shielding film is electrically floating or electrically connected to a ground (GND) terminal, and wherein the shielding film fully overlaps the inductor in the direction of a vertical projection to the SOC die.
